(19) United States
(12) Patent Application Publication
(10) Pub. No.: US 2011/0127590 A1
(43) Pub. Date: Jun. 2, 2011

(54) INCREASING STABILITY OF A HIGH-K GATE DIELECTRIC OF A HIGH-K GATE STACK BY AN OXYGEN RICH TITANIUM NITRIDE CAP LAYER

(76) Inventors: Robert Binder, Dresden (DE); Joachim Metzger, Butzbach (DE); Klaus Hempel, Dresden (DE)

(21) Appl. No.: 12/901,631

(22) Filed: Oct. 11, 2010

(30) Foreign Application Priority Data
Nov. 30, 2009 (DE) 102009047307.6

(51) Int. Cl. H01L 29/772; H01L 21/336

(52) U.S. Cl. 257/288; 438/287; 257/E21.409; 257/E29.242

(57) ABSTRACT

In a replacement gate approach, the oxygen contents of a cap material may be increased, thereby providing more stable characteristics of the cap material itself and of the high-k dielectric material. Consequently, upon providing a work function adjusting metal species at a very advanced manufacturing stage, corresponding additional treatments may be reduced in number or may even be completely avoided, while at the same time threshold voltage variations may be reduced.

### BACKGROUND OF THE INVENTION

1. Field of the Invention

Generally, the present disclosure relates to the fabrication of highly sophisticated integrated circuits including advanced transistor elements having gate structures of increased capacitance including a high-k gate dielectric and a metal-containing cap layer.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of integrated circuits, field effect transistors represent one important type of circuit element that substantially determines performance of the integrated circuits. Generally, a plurality of process technologies are currently practiced for forming field effect transistors, wherein, for many types of complex circuitry, MOS technology is one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Hence, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length, and associated therewith the reduction of channel resistivity, which in turn causes an increase of gate resistivity due to the reduced dimensions, is a dominant design criterion for accomplishing an increase in the operating speed of the integrated circuits.

Presently, the vast majority of integrated circuits are based on silicon due to its substantially unlimited availability, the well-understood characteristics of silicon and related materials and processes and the experience gathered during the last 50 years. Therefore, silicon will likely remain the material of choice for future circuit generations designed for mass products. One reason for the dominant role of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, during anneal cycles to activate dopants and to cure crystal damage without sacrificing the electrical characteristics of the interface.

For the reasons pointed out above, in field effect transistors, silicon dioxide is preferably used as a base material of a gate insulation layer that separates the gate electrode, frequently comprised of polysilicon or other materials, from the silicon channel region. In steadily improving device performance of field effect transistors, the length of the channel region has been continuously decreased to improve switching speed and drive current capability. Since the transistor performance is controlled by the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length requires an increased capacitive coupling to avoid the so-called short channel behavior during transistor operation. The short channel behavior may lead to an increased leakage current and to a dependence of the threshold voltage on the channel length. Aggressively scaled transistor devices with a relatively low supply voltage and thus reduced threshold voltage may suffer from an exponential increase of the leakage current, while also requiring enhanced capacitive coupling of the gate electrode to the channel region. Thus, the thickness of the silicon dioxide layer has to be correspondingly decreased to provide the required capacitance between the gate and the channel region. For example, a channel length of approximately 80 nm may require a gate dielectric made of silicon dioxide as thin as approximately 1.2 nm. Although usage of high speed transistor elements having an extremely short channel may be restricted to high speed signal paths, whereas transistor elements with a longer channel may be used for less critical circuit portions, such as storage transistor elements, the relatively high leakage current caused by direct tunneling of charge carriers through an ultra-thin silicon dioxide gate insulation layer may reach values for an oxide thickness in the range of 1-2 nm that may not be compatible with requirements for many types of circuits, even if only transistors in speed critical paths are formed on the basis of an extremely thin gate oxide.

Therefore, replacing silicon dioxide as the material for gate insulation layers has been considered, particularly for extremely thin silicon dioxide gate layers. Possible alternative materials include materials that exhibit a significantly higher permittivity so that a physically greater thickness of a correspondingly formed gate insulation layer provides a capacitive coupling that would be obtained by an extremely thin silicon dioxide layer. It has thus been suggested to replace silicon dioxide with high permittivity materials, such as tantalum oxide (Ta₂O₅), with a k of approximately 25, strontium titanium oxide (SrTiO₃), having a k of approximately 150, hafnium oxide (HfOₓ), HfSiO, zirconium oxide (ZrO₂) and the like.

Additionally, transistor performance may be increased by providing an appropriate conductive material for the gate electrode so as to replace the usually used polysilicon material, since polysilicon may suffer from charge carrier depletion at the vicinity of the interface to the gate dielectric, thereby reducing the effective capacitance between the channel region and the gate electrode. Thus, a gate stack has been suggested in which a high-k dielectric material provides an increased capacitance based on the same thickness as a silicon dioxide layer, while, additionally, leakage currents are kept at an acceptable level. On the other hand, the non-polysilicon material, such as titanium nitride, may be formed so as to connect to the high-k dielectric material, thereby substantially avoiding the presence of a depletion zone.

After forming sophisticated gate structures including a high-k dielectric and a metal-based gate material, however, high temperature treatments may be required, which may result in a shift of the work function and a reduction of the permittivity of the gate dielectric, which may also be associated with an increase of layer thickness, thereby offsetting many of the advantages of the high-k dielectric in combination and the metal material.

For this reason, strategies have been developed in which the actual electrode metal including an appropriate work function adjusting species for P-channel transistors and N-channel transistors, respectively, are provided in a late manufacturing stage, i.e., after any such high temperature processes. In these so-called replacement gate approaches, a place-holder material, such as polysilicon, is removed in a manufacturing state, in which the gate electrode structure has been laterally embedded in an interlayer dielectric material. On the basis of selective etch techniques, the placeholder material is removed, while the titanium nitride material acts as an etch stop layer in order to protect the underlying sensitive high-k dielectric material, which is frequently being provided in the form of a hafnium-based oxide material. Thereafter, a work function metal may be formed, possibly in combination with additional conductive barrier materials, such as tantalum nitride and the like, in order to achieve the required band gap adaptation of the channel region in combination with the complex gate dielectric material and the adjacent titanium nitride material in combination with the work function adjusting metals species. For example, lanthanum may be used in combination with N-channel transistors, while aluminum may be applied in P-channel transistors. The adjustment of an appropriate work function and thus threshold of sophisticated transistor elements may be a complex task, in particular when transistors of basically the same configuration may have to be provided with different threshold voltages, in order to comply with various requirements in the different signal paths of complex integrated circuits. For example, low threshold voltage transistors with extremely short channels may be required in fast digital signal paths, while, in other cases, an increased threshold voltage may be required in less critical signal paths, while the basic transistor configuration, for instance, may be substantially identical. Consequently, a plurality of complex mechanisms have been developed, which may allow an adjustment of different threshold voltages and other transistor characteristics, such as leakage current and the like. For example, gate dielectric materials of different thicknesses, otherwise substantially the same material composition, very complex drain and source dopant profiles in combination with complex counter-doping processes, also referred to as halo implantation and the like, may typically be required for achieving the desired threshold characteristics. Consequently, in the context of sophisticated high-k metal gate electrode structures, any process-related variations in providing the gate electrode structure may have a significant influence on the finally-obtained transistor characteristics. For this reason, in the replacement gate approach, complex process techniques may be applied to suppress process-induced variations of the gate electrode structure upon replacing the placeholder material with the actual electrode material including the work function adjusting species. However, these process techniques may result in a complex process flow and may nevertheless suffer from reduced flexibility, for instance due to thermal budget constraints and the like, as will be explained in more detail with reference to FIGS. 1a-1b.

FIG. 1a schematically illustrates a cross-sectional view of a semiconductor device 100 in a manufacturing stage in which a gate layer stack 110S is formed on a semiconductor region 102, which in turn is formed on a substrate 101. The substrate 101 represents any appropriate carrier material, such as a semiconductor substrate and the like. Furthermore, the semiconductor region 102 may comprise a significant amount of silicon in a crystalline state, wherein the semiconductor region 102 may be laterally delineated by any appropriate isolation structures (not shown), such as trench isolations and the like. Furthermore, if a silicon-on-insulator (SOI) configuration is required, a buried insulating material (not shown) may be provided between the substrate 101 and the semiconductor region 102. It should be appreciated that the semiconductor region 102, which may also be considered as an active region of a transistor still to be formed, may have any appropriate dopant profile as may be required for defining the basic conductivity type and other transistor characteristics, such as threshold voltage and the like, which, however, may also strongly depend on the further configuration, for instance the dopant profile of drain and source regions still to be formed, the characteristics of a gate electrode structure to be formed on the basis of the gate layer stack 1105 and the like, as previously explained.

The gate layer stack 1105 comprises a gate dielectric material formed on the semiconductor region 102 and typically comprises a base layer 111, which may be comprised of any appropriate “conventional” dielectric material, such as silicon dioxide, silicon oxynitride and the like. The base layer 111 may provide superior interface characteristics, while capacitive coupling and the enhanced leakage current behavior may be obtained on the basis of a high-k dielectric material 112, such as a hafnium oxide based material and the like. For example, the base layer 111 may be provided with a thickness of less than 10 Å, while the layer 112 may have a thickness of 15-30 Å, depending on the transistor requirements. However, as explained above, a titanium nitride layer 113 is formed on the high-k dielectric material 112, thereby reducing the interaction of the sensitive material 112 with other materials and reactive process environments during the further processing of the device 100. Moreover, the gate layer stack 1105 comprises a placeholder material 114, such as a silicon material, which, in the manufacturing stage shown, may be provided in the form of an amorphous silicon material. Additionally, a dielectric cap material 115, such as silicon nitride, possibly in combination with silicon dioxide and the like, may be provided in the gate layer stack 110S as is required for the further processing of the device 100. It should be appreciated that additional material or material systems may be provided above the gate layer stack 110S, such as hard mask materials, in the form of silicon dioxide, amorphous carbon, silicon oxynitride and the like.

Typically, the semiconductor device 100 as shown in FIG. 1a is formed in accordance with well-established process techniques for forming the semiconductor region 102, for instance, by providing isolation structures and the like, in combination with implantation processes, in order to generate the required basic dopant distribution in the semiconductor region 102. Thereafter, the base layer 111 may be formed by deposition and/or oxidation, followed by the deposition of the high-k dielectric material 112 on the basis of chemical vapor deposition (CVD) techniques and the like. Thereafter, the titanium nitride layer 113 may be deposited, for instance, by physical vapor deposition in the form of a sputter deposition process. Thereafter, the silicon material 114 is deposited, for instance, by low pressure CVD techniques and the like. Next, the dielectric cap material 115 is deposited, for instance, by thermally activated CVD, plasma enhanced CVD and the like. Thereafter, the gate layer stack 110S is patterned on the basis of sophisticated lithography techniques in combination with advanced etch processes in order to obtain a gate electrode structure having the desired critical dimensions. After the patterning of the gate layer stack 110S, further processes have to be performed, for instance for forming drain and source regions in the semiconductor region 102, which may be associated with respective masking processes and high temperature anneal processes so that the resulting gate electrode structure may experience a plurality of process conditions at high temperatures in combination with a plurality of reactive process atmospheres, which may have a more or less pronounced influence on the layers 112 and 113, which in turn may thus influence the finally-obtained work function and thus threshold voltage of a transistor still to be formed. For example, without intending to restrict the present application to the following explanation, it is believed that the finally obtained characteristics of the gate dielectric material, i.e., the materials 111 and 112, may strongly depend on the presence of oxygen vacancies in the material 112, which may thus in turn affect the electronic characteristics of the interface between the semiconductor region 102 and the gate dielectric material, i.e., the layer 111. On the other hand, the number and density of oxygen vacancies may depend on the characteristics of the titanium nitride cap material 113, which in turn may be strongly influenced on the entire process history and in particular the history of high temperature processes performed on the device 100. For example, an oxidation rate, i.e., the rate of oxygen incorporation into the layer 113, may strongly depend on the previous process history, wherein the amount of oxygen may in turn significantly influence the state of the high-k dielectric material 112. Consequently, in a very advanced manufacturing stage, a plurality of complex process steps, such as anneal processes based on more or less complex process atmospheres, may be established in an attempt to provide uniform process conditions to reduce process variations, which may otherwise contribute to significantly varying threshold voltages, in particular when various mechanisms may be applied so as to intentionally adjust the threshold voltage of different transistor types in accordance with the overall circuit requirements.

FIG. 1b schematically illustrates the device 100 in a further advanced manufacturing stage. As illustrated, a transistor 150 is formed in and above the semiconductor region 102 and comprises a gate electrode structure 110, which, in the manufacturing stage shown, includes the gate dielectric materials 111 and 112 and the titanium nitride cap material 113. Furthermore, a protective sidewall spacer 116, such as a silicon nitride spacer, may laterally delineate a gate opening 114A obtained after the removal of the placeholder material 114. Moreover, the transistor 150 comprises drain and source regions 152, possibly in combination with metal silicide regions 153 in order to reduce the overall contact resistance of the transistor 150. Additionally, a channel region 151 is formed below the gate dielectric material 111. Depending on the overall process strategy, a spacer structure 154 may be provided, for instance in the form of a silicon nitride material, in combination with silicon dioxide and the like. Furthermore, an interlayer dielectric material 120 laterally encloses the gate electrode structure 110 and may comprise any appropriate material, such as an etch stop layer 121, for instance in the form of silicon nitride, followed by a silicon dioxide material 122.

The semiconductor device 100 as illustrated in FIG. 1b may be formed in accordance with process techniques as described above for patterning the gate electrode structure 110 and providing the drain and source regions 152, which may be accomplished on the basis of the sidewall spacer structure 154 in order to obtain the desired complex lateral and vertical dopant profile. After any anneal processes, the metal silicide regions 153 may be formed in accordance with any appropriate process strategy, followed by the deposition of the interlayer dielectric material 120, which is subsequently planarized, for instance by chemical mechanical polishing (CMP), etch processes and the like, thereby exposing the material 114, which is then removed on the basis of appropriate selective etch recipes, for instance using TMAH (tetra methyl ammonium hydroxide) and the like. During the etch process, the titanium nitride cap layer 113 acts as an etch stop material. As previously discussed, since the finally obtained characteristics of the gate electrode structure 110 in terms of work function and the like is strongly influenced on the condition of the layers 113 and 112, typically, prior to and/or after the deposition of at least a material layer 117 including a work function adjusting metal, respective treatments 103 are performed. For example, the cap material 113 may be exposed to a specifically designed gas atmosphere, such as a forming gas atmosphere, which is to be understood as a mixture of hydrogen gas and nitrogen gas, at the same time applying appropriated temperatures, which are compatible with the configuration of the device 100 in the manufacturing stage shown. That is, elevated temperatures may be applied to modify the characteristics of the cap material 113 on the basis of chemicals, gases, and, in particular, elevated temperatures, wherein, however, a moderately narrow process window may exist, since, otherwise, other significant modifications may be caused, for instance in the metal silicide regions 153 and the like. Thus, in some process strategies, the treatment 103 may be performed upon exposure of the cap material 113 and thereafter the material layer 117, which may, for instance, comprise any barrier materials, such as tantalum nitride, in combination with a work function adjusting species, such as aluminum for P-channel transistors or lanthanum for N-channel transistors, may be deposited by any appropriate deposition technique, such as physical vapor deposition, chemical vapor deposition and the like. In some strategies, in addition to or alternatively to the treatment 103, prior to the deposition of the material 117, a further treatment may be performed on the basis of elevated temperatures, which, however, may also be constrained by the thermal budget of the manufacturing stage shown, in order to further adjust the finally-obtained threshold voltage. However, since the effect of the one or more treatments 103 may strongly depend on the process history, for instance, the degree of oxygen in the material layer 113 may depend on the previously applied process temperatures, which may depend on the overall device requirements, for instance, in view of diffusion of dopants and the like, the final adjustment of the transistor characteristics in terms of work function and/or threshold voltage may thus represent a “combination” of a plurality of process variations of the previously performed manufacturing processes. For this reason, the treatment 103 may result in a moderately wide range of threshold voltages for the same transistor type across the entire substrate 101 after the stabilization obtained by the treatment 103. Consequently, although the replacement gate approach may generally provide a high degree of flexibility in adjusting the threshold voltages of transistors in a very advanced manufacturing stage, the process history may nevertheless influence the state of the high-k dielectric material and the conductive titanium nitride cap layer, which in turn may contribute to a pronounced variation of transistor threshold voltage, in particular if different threshold voltage levels may be required in sophisticated semiconductor devices.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and techniques in which a conductive cap material of a high-k metal gate electrode structure may be stabilized in an early manufacturing stage, thereby endowing the cap material with superior chemical and temperature stability, which may result in reduced threshold voltage variations upon adjusting the threshold voltage of the transistor by using a specified electrode material. In some illustrative aspects disclosed herein, a replacement gate approach may be applied, wherein the superior stability of the cap material formed on the gate dielectric layer may enable a significant reduction in process complexity, for instance by avoiding at least one treatment used in conventional approaches for adjusting the threshold voltage, while at the same time providing reduced threshold voltage variations. In illustrative aspects disclosed herein, the cap material may be provided in the form of a material including titanium, nitrogen and oxygen, which may also be referred to as an oxygen enriched titanium nitride material, wherein the additional oxygen contents in the cap layer may act as a source for supplying oxygen to the underlying high-k dielectric material, thereby reducing the amount of oxygen vacancies, which are believed to cause a significant degree of work function variation in conventional process strategies, as described above. It should be appreciated, however, that the present disclosure is not to be considered as being restricted to this explanation, as, generally, providing an increased amount of oxygen in the titanium and nitrogen containing cap material may result in superior transistor characteristics, even if further treatments on the basis of dedicated gases and chemicals in combination with elevated temperatures may be omitted or reduced in a very advanced manufacturing stage.

One illustrative method disclosed herein relates to forming a high-k gate electrode structure of a semiconductor device. The method comprises forming a high-k dielectric material above a semiconductor region and forming a titanium, nitrogen and oxygen-containing cap layer on the high-k dielectric material. Additionally, the method comprises forming an electrode material above the cap layer, wherein the electrode material comprises a metal species for adjusting a work function of the high-k gate electrode structure.

A further illustrative method disclosed herein comprises forming a gate electrode structure on a semiconductor region of a semiconductor device. The gate electrode structure comprises a titanium, nitrogen and oxygen-containing cap layer formed above a high-k dielectric material. Furthermore, the gate electrode structure comprises a placeholder material formed above the cap layer. The method further comprises forming drain and source regions in the semiconductor region and replacing the placeholder material with an electrode material after forming the drain and source regions, wherein the electrode material comprises a metal species for adjusting a work function of the gate electrode structure.

One illustrative transistor device disclosed herein comprises a gate electrode structure, which comprises a titanium, oxygen and nitrogen-containing cap layer on a gate insulation layer that in turn comprises a high-k dielectric material. The gate electrode structure further comprises an electrode material formed above the cap layer and comprising a work function adjusting species.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a semiconductor device during various manufacturing stages in forming a high-k metal gate electrode structure on the basis of a replacement gate approach by applying conventional strategies in adjusting the final work function and thus threshold voltage of the transistor;

FIGS. 2a-2g schematically illustrate cross-sectional views of a semiconductor device during various manufacturing stages in forming a high-k metal gate electrode structure on the basis of a cap layer formed on the high-k dielectric material and which may have a superior stability and include an increased oxygen content, according to illustrative embodiments; and

FIG. 2h schematically illustrates a cross-sectional view of the semiconductor device in an early manufacturing stage in embodiments in which a strain-inducing semiconductor alloy may be formed in the active region on the basis of a thin sidewall spacer structure and the cap material having the superior stability.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure addresses the problem of work function and thus threshold voltage variation in sophisticated transistors having a high-k metal gate electrode structure, which, in some illustrative embodiments, may be formed on the basis of a replacement gate approach. To this end, the stability of a complex material system including the high-k dielectric material and a cap material, which, in some illustrative embodiments, may be provided in the form of a titanium and nitrogen-containing material, is improved by incorporating an increased amount of oxygen into the cap layer on the basis of wellcontrolled process conditions. Without intending to restrict the present application to any theory, it is assumed that the increased oxygen contents may act as a source for reducing the number of oxygen vacancies in the high-k dielectric material, thereby reducing the degree of threshold voltage variation, which may conventionally be caused by, among other things, the process history that is experienced by the cap material and high-k dielectric material prior to providing a desired work function adjusting species. Moreover, it is believed that an increased degree of oxygen may contribute to a superior stability of the cap layer itself, thereby also providing superior uniformity during the further processing of a complex semiconductor device. For example, the superior stability of the cap material may enable selecting a reduced thickness of protective sidewall spacer elements, which are typically provided to preserve integrity of the sensitive material during the further processing. However, in many approaches, efficient mechanisms for enhancing performance of transistor elements may have to be implemented, for instance in the form of an embedded strain-inducing semiconductor mixture or alloy, which may, thus, create a desired type of strain in the adjacent channel region. Since the efficiency of such a mechanism strongly depends on the lateral offset of the strain-inducing semiconductor material from the channel region, and since this offset is substantially determined by the width of the protective spacer elements, a further reduction in spacer width may conventionally be associated with an increased probability of negatively affecting integrity of the cap material during the complex sequence for forming cavities in the semiconductor material and refilling the same with the strain-inducing semiconductor alloy. By increasing the stability of the cap material, a deterioration of the cap material may be reduced or avoided upon reducing the width of the protective spacer elements, thereby enabling a more efficient strain-inducing mechanism.

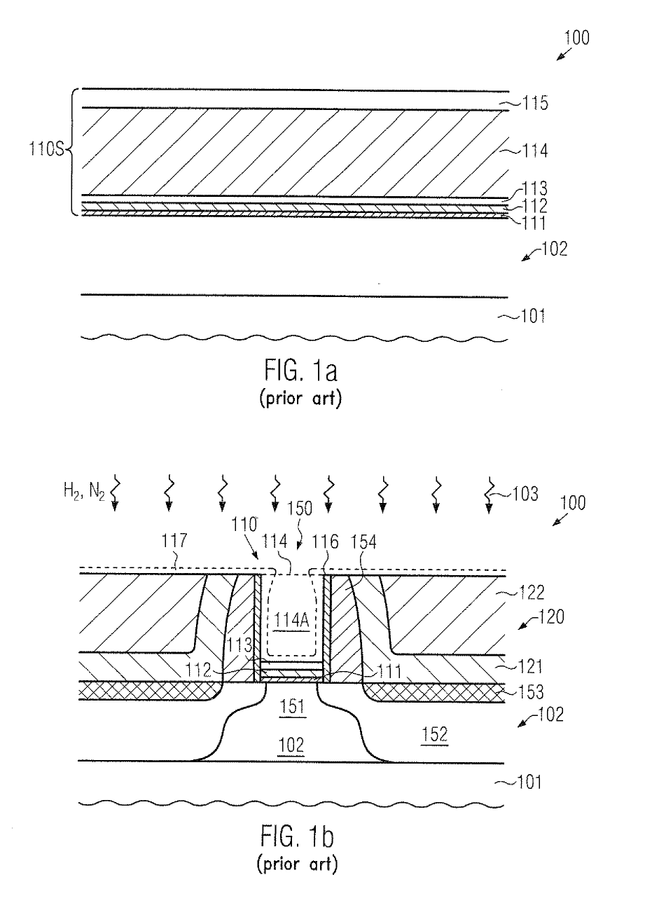

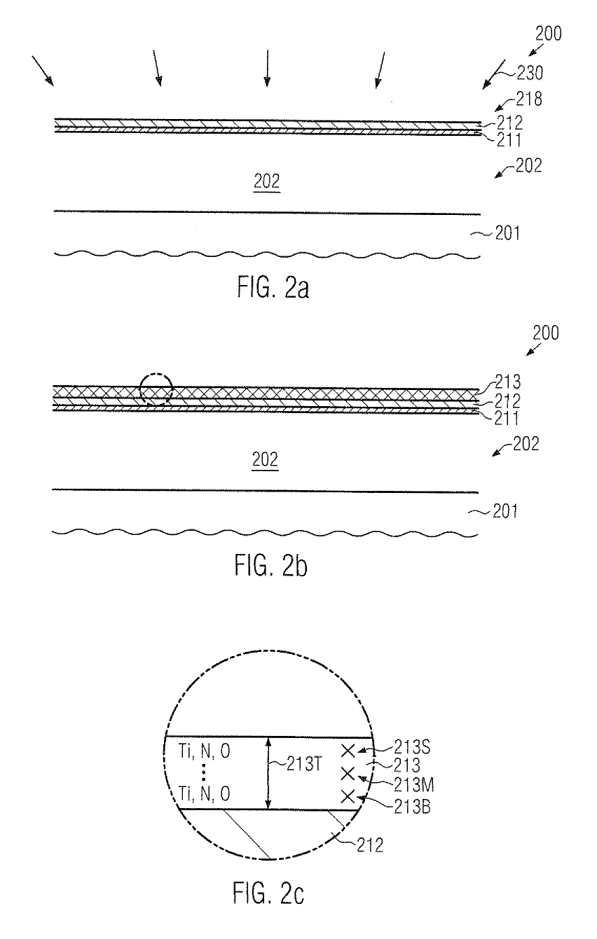

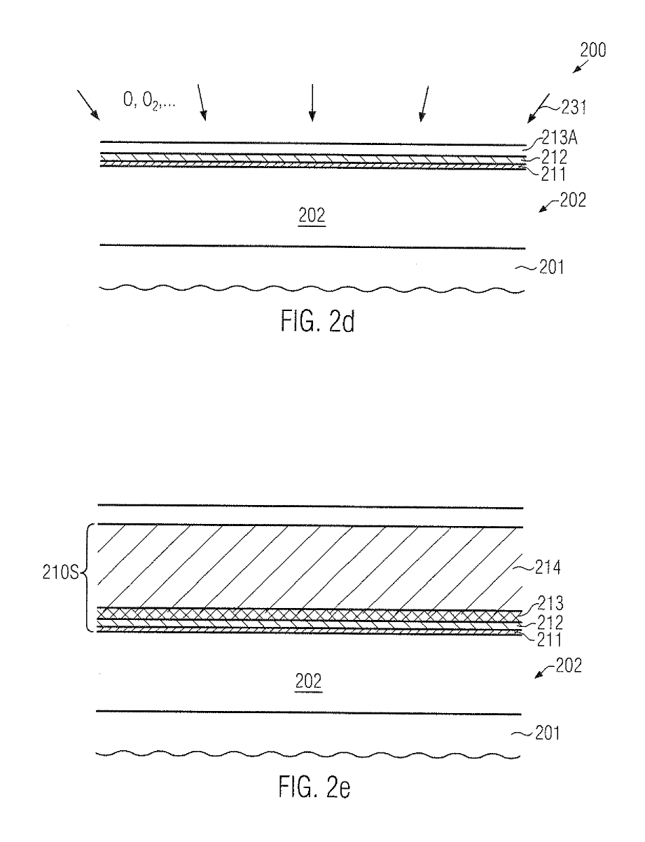

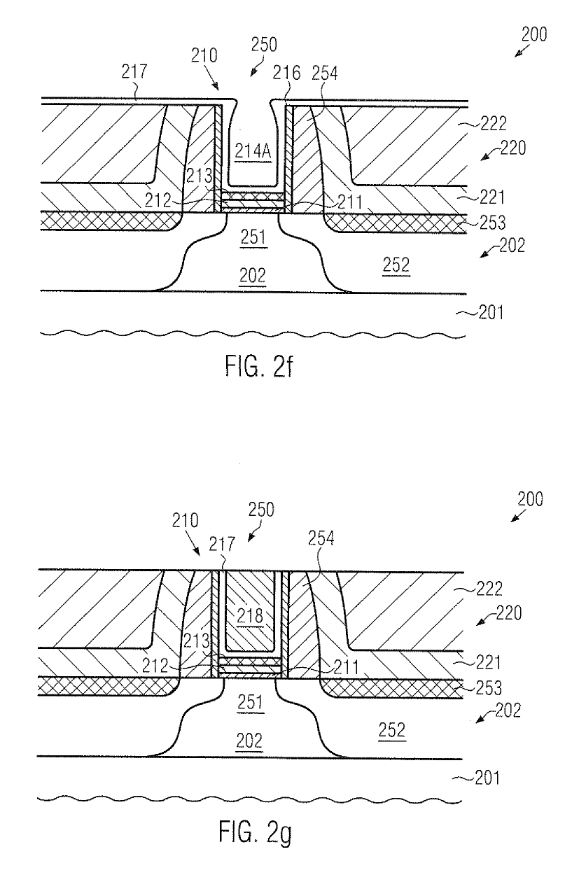

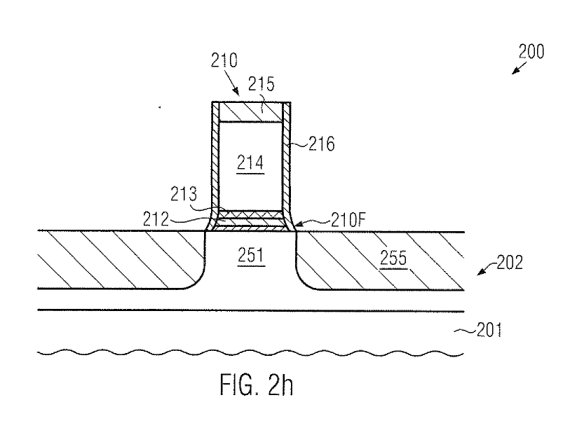

With reference to FIGS. 2a-2h, further illustrative embodiments will now be described in more detail, wherein reference may also be made to FIGS. 1a-1b, if appropriate.

FIG. 2a schematically illustrates a semiconductor device 200 comprising a substrate 201, above which may be formed a semiconductor region 202, which is to be understood as a part of a semiconductor layer, which may also comprise isolation structures (not shown) that laterally delineate the semiconductor region 202. The semiconductor region 202 may comprise silicon, since presently, and in the near future, complex semiconductor devices are, and will be, fabricated on the basis of silicon material. It should be appreciated, however, that other semiconductor materials may be used, if considered appropriate. For example, the semiconductor region 202 may comprise germanium, silicon/germanium in the form of a semiconductor mixture or any other appropriate semiconductor materials. However, any appropriate dopant distribution may be provided in the semiconductor region 202 in accordance with the requirements for forming one or more transistors in and above the semiconductor region 202. For example, the region 202 may represent the active region of one or more P-channel transistors and/or N-channel transistors, depending on the overall process requirements. Moreover, with respect to the substrate 201 and the semiconductor region 202, the same criteria may apply as previously explained with reference to the semiconductor device 100. Furthermore, in the manufacturing stage shown, a gate dielectric material 218 may be formed on the semiconductor region 202 and may comprise a high-k dielectric material 212. Furthermore, as previously discussed, a base layer 211, for instance in the form of silicon dioxide, silicon oxynitride and the like, may be provided between the high-k material 212 and the semiconductor region 202, for instance, in order to improve the interface characteristics and the like. In some illustrative embodiments, the high-k dielectric material 212 may comprise hafnium and oxide, for instance in the form of hafnium oxide, hafnium silicon oxide and the like. In other cases, the high-k dielectric material 212 may represent an oxide of other metal species, such as zirconium and the like.

The semiconductor region 202 and the gate dielectric material 218 may be formed on the basis of any appropriate process techniques, as is, for instance, explained above with reference to the device 100. After forming the gate dielectric material 218, the semiconductor device 200 may be exposed to a deposition ambient 230, in which a cap material, which typically has a certain conductivity, is formed on the gate dielectric material 218 in order to provide superior integrity, as is also previously discussed. In one illustrative embodiment, the deposition ambient 230 is established on the basis of titanium, nitrogen and oxygen in order to deposit a material layer including these species, wherein a ratio of the individual species may be adjusted by controlling appropriate process parameters in the deposition ambient 230. For example, the deposition process 230 may be performed on the basis of a physical vapor deposition technique, in which an appropriate target material, such as a titanium material, a titanium oxide material and the like, may be exposed to a particle bombardment, for instance in the form of argon ions and the like, so as to release titanium and possibly other atoms contained in the target material into the deposition ambient of the process 230. For this purpose, a plurality of well-established process recipes and process tools are available in semiconductor fabrication facilities. Moreover, additional species, such as nitrogen and/or oxygen, may be introduced into the ambient 230 by establishing a corresponding gas flow in order to increasingly deposit various species on and above the material 212. Consequently, since any of these process parameters may be controlled in a highly accurate manner, the desired composition of the resulting material layer may also be controlled with a high degree of precision. It should be appreciated that appropriate process parameters may be readily established on the basis of currently available process recipes by examining the material composition of the resulting layer for a plurality of different process parameters.

FIG. 2b schematically illustrates the semiconductor device 200 with a cap layer 213 formed on the high-k dielectric material 212 with a desired thickness and material composition that are obtained by controlling the respective process parameters of the process 230 of FIG. 2a. In some illustrative embodiments, the cap layer 213 may be provided in the form of a titanium, nitrogen and oxygen-containing material composition, wherein a fraction of the oxygen species may be in the range of approximately 5-30 atomic percent. Thus, by appropriately controlling the composition of the layer 213, a specific configuration may be achieved with a high degree of accuracy, wherein the additional oxygen may impart superior chemical stability to the layer 213 and may also act as a source for providing additional oxygen atoms to the material 213, thereby reducing any oxygen vacancies, as explained above.

FIG. 2c schematically illustrates an enlarged view of a portion of the layers 212 and 213 according to some illustrative embodiment, in which the species titanium, nitrogen and oxygen may have a substantially uniform distribution across the thickness 213T of the layer 213. In this case, a substantially uniform distribution is to be understood that the concentration of each of the species contained in the layer 213, except for any unintentionally incorporated impurities, may vary by less than approximately 5% relative to an average concentration of the corresponding species at any height along the thickness 213T of the layer 213. For instance, the oxygen concentration at three different height levels 213S, 213M, 213B, i.e., at the surface of the layer 213, in the center of the layer 213 and at the bottom on the layer 213, may differ from each other by less than 5% of an average concentration determined on the basis of these individual concentration values.

FIG. 2d schematically illustrates the device 200 according to further illustrative embodiments in which a cap layer 213A may be formed on the high-k dielectric material 212. The cap layer 213A may comprise a desired composition, such as a titanium nitride mixture and the like. For example, well-established deposition strategies may be applied to form the layer 213A, as is also previously discussed with reference to the semiconductor device 100. Moreover, in order to increase the oxygen content of the layer 213A, a treatment 231 may be performed on the basis of an oxygen-containing ambient. For example, in some illustrative embodiments, the treatment 231 may be performed as a plasma assisted process, during which oxygen radicals may interact with the material of the layer 213A, thereby “oxidizing” to a certain degree the base material of the layer 213A. For example, appropriate plasma recipes may be applied by using well-established oxygen plasma conditions, which are also frequently used in removal processes for stripping resist material by ashing the resist material. Based on corresponding process recipes and process tools, the treatment 231 may be performed for approximately 5-60 seconds, thereby obtaining a desired oxygen fraction in the layer 213A for given process conditions for establishing the plasma ambient 231. In other illustrative embodiments, the treatment 231 may be performed on the basis of any other reactive oxygen-containing process ambient, for instance by establishing a gaseous ambient and using elevated temperatures in the range of approximately 150-300° C., thereby also efficiently incorporating the oxygen species into the layer 213A. Also in this case, the process parameters may be controlled with a high degree of accuracy, for instance by establishing specified gas flow rates, controlling the process temperature and the like. In still other illustrative embodiments, the treatment 231 may be performed on the basis of a reactive wet chemical process ambient, in which an oxidizing agent may be supplied, for instance in combination with appropriate temperatures, in order to incorporate a desired amount of oxygen species into the layer 213A.

FIG. 2e schematically illustrates the semiconductor device 200 after the treatment 231 of FIG. 2d, thereby “converting” the layer 213A (FIG. 2d) into the layer 213 having incorporated therein a desired amount of oxygen.

On the basis of the layer 213 obtained by any of the above-described process techniques, the processing may be continued by depositing one or more materials so as to form a gate layer stack 210S, which may comprise a placeholder material 214 in combination with one or more additional materials, as is also previously discussed with reference to the semiconductor device 100. It should be appreciated that, during the deposition of any further materials of the gate layer stack 210S and during the patterning thereof, the material 213 having the increased oxygen content provides superior uniformity of the characteristics of the layer 213 itself and also of the layer 212.

FIG. 2f schematically illustrates the semiconductor device 200 in a further advanced manufacturing stage. As illustrated, a transistor 250 may be formed in and above the semiconductor region 202 and may comprise drain and source regions 252, a channel region 251 and metal silicide regions 253. Moreover, a gate electrode structure 210 may be formed on the semiconductor region 202 and may comprise the dielectric layers 211 and 212, which may still be covered by the cap layer 213. Furthermore, a protective spacer 216, for instance in the form of a thin oxide material (not shown) and a silicon nitride material may be provided and may laterally delineate a gate opening 214A. Furthermore, a spacer structure 254 may be formed on the spacer 216 and may have any appropriate configuration. Additionally, an interlayer dielectric material 220, for instance comprising two or more individual material layers 221, 222, may be provided so as to laterally enclose the gate electrode structure 210.

With respect to any manufacturing techniques for forming the semiconductor device 200 as illustrated in FIG. 2f, the same criteria may apply as previously discussed with reference to the semiconductor device 100 in order to provide the drain and source regions 252, the metal silicide regions 253, the gate electrode structure 210 and the interlayer dielectric material 220. Furthermore, the placeholder material 214 (FIG. 2e) may be removed from the gate electrode structure 210 on the basis of any appropriate etch technique, as is also previously described with reference to the device 100. In some illustrative embodiments, after exposing the cap layer 213 in the gate opening 214A, any additional treatments for adjusting or stabilizing the configuration of the layers 213 and 212 may be omitted, since the superior stability and/or the increased oxygen contents of the layer 213 may result in a high degree of uniformity, since any previous processes may significantly less effect the status of the layers 212 and 213. For example, it is assumed that during the previous high temperature processes the increased oxygen contents in the layer 213 may reduce the density of any oxygen vacancies in the material 212, thereby contributing to a more stable status of this material. Furthermore, the additional oxygen species in the layer 213 may provide superior integrity of the layer 213 itself, for instance, in view of chemical stability, temperature dependence and the like. Consequently, a material 217, which may include any appropriate work function adjusting metal species, such as aluminum for P-channel transistors or lanthanum for N-channel transistors and the like, may be formed within the opening 214A, possibly in combination with any conductive barrier materials, if required, without any complex pre-deposition treatments. Thus, overall throughput of the manufacturing flow may be significantly enhanced, while at the same time superior stability of the configuration of the gate electrode structure 210 may be accomplished. After the deposition of the material layer 217, the processing may be continued by depositing any further material and patterning the same, if required, in order to provide appropriate work function metal species for any type of transistors in the device 200. In some illustrative embodiments, the further processing may not require any dedicated treatments for adjusting the work function, for instance, on the basis of elevated temperatures, possibly in combination with specific gas atmospheres, as are typically applied in conventional strategies. For example, a forming gas atmosphere based on elevated temperatures may not be required in some illustrative embodiments and may thus contribute to a superior process efficiency. Thereafter, any further electrode material may be formed in the opening 214A on the basis of any appropriate deposition technique, such as CVD, sputter deposition, electrochemical deposition and the like.

FIG. 2g schematically illustrates the semiconductor device 200 in a further advanced manufacturing stage in which the material 217 in combination with a further conductive material 218 may represent an electrode material of the gate electrode structure 210. For instance, the conductive material 218 may be provided in the form of aluminum, while, as discussed above, the material layer 217 may comprise one or more individual material layers, at least one of which may include the desired work function adjusting species. As discussed above, the material 218 may be provided on the basis of any appropriate deposition technique, followed by the removal of any excess material, which may be accomplished by CMP, etching, electro-CMP, electro-etching and the like. Consequently, the gate electrode structure 210 may be provided with superior uniformity in terms of work function and thus threshold voltage of the transistor 250, while providing the possibility of reducing overall process complexity compared to conventional approaches.

FIG. 2h schematically illustrates the semiconductor device 200 according to further illustrative embodiments in which a strain-inducing semiconductor alloy 255, such as a silicon/germanium alloy and the like, may be formed in the semiconductor region 202 in order to create a desired strain component in the channel region 251. For this purpose, the gate electrode structure 210 may comprise a dielectric cap material 215, such as a silicon nitride material and the like, in combination with the spacer element 216, for instance in the form of an oxide material (not shown) and a silicon nitride material, so as to encapsulate the placeholder material 214 and to maintain integrity of sidewalls of the sensitive materials 213 and 212.

The gate electrode structure 210 as illustrated in FIG. 2h may be formed on the basis of any appropriate manufacturing strategy. That is, after patterning the gate layer stack, the spacer element 216 may be formed, for instance, by oxidizing the placeholder material 214 and depositing a silicon nitride material on the basis of thermally activated and/or plasma-enhanced CVD techniques, which may subsequently be etched by appropriate plasma-assisted etch techniques. Thus, the materials 215 and 216 may act as an etch mask and a growth mask during the further processing of the device 200. That is, cavities may be formed in the semiconductor region 202 on the basis of well-established anisotropic etch techniques, followed by a sequence for refilling the cavities with the material 255. Consequently, the lateral offset of the material 255 from the channel region 251 and thus the straininducing efficiency of the material 255 may depend on the width of the spacer 216, which is thus a compromise between reliable coverage of the materials 214, 213 and 212 and a desired minimum offset of the material 255. Thus, upon further reducing the width of the spacer 216 in an attempt to obtain a higher strain component in the channel region 251, in particular, a portion of the material 213 may be exposed during the complex process sequence, which may require a plurality of cleaning processes to be performed on the basis of sulfuric acid and the like. For example, upon patterning the gate electrode structure 210, a more or less pronounced increased gate length at the foot of the gate electrode structure 210, indicated as 210F, may occur, which in turn may result in a significantly reduced thickness of the spacer 216 and thus in a less reliable coverage of a corresponding portion of the material 213, in particular when, generally, a width of the spacer 216 is to be reduced. Thus, during highly efficient but aggressive cleaning recipes, the cap material may be attacked and may be removed, thereby causing significant irregularities. However, due to the increased oxygen contents of the material 213, the chemical stability thereof may be significantly enhanced, thereby reducing the effects of chemical agents, such as cleaning agents, even though a reduced width of the spacer 216 may be applied. Consequently, for an otherwise identical configuration of the gate electrode structure 210, the provision of the layer 213 having the increased oxygen contents may enable a reduced width of the spacer 216 compared to conventional strategies, thereby increasing performance of the resulting transistor device.

As a result, the present disclosure provides semiconductor devices and manufacturing techniques in which the cap material formed on a high-k dielectric material of a gate electrode structure may receive an increased oxygen content, thereby imparting superior stability at least to the underlying high-k dielectric material. Consequently, the number of complex processes for adjusting the final work function at a very late manufacturing stage in a replacement gate approach may be reduced or any such treatments may even be completely avoided, thereby resulting in a very efficient process flow, while at the same time threshold voltage variations of transistors of the same type may be significantly reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a high-k gate electrode structure of a semiconductor device, the method comprising:
forming a high-k dielectric material above a semiconductor region;
forming a titanium, nitrogen and oxygen containing cap layer on said high-k dielectric material; and
forming an electrode material above said cap layer, said electrode material comprising a metal species for adjusting a work function of said high-k gate electrode structure.

2. The method of claim 1, wherein forming said cap layer comprises forming a titanium nitride layer and exposing said titanium nitride layer to a controlled oxidizing ambient.

3. The method of claim 2, wherein said controlled oxidizing ambient is established by generating a plasma.

4. The method of claim 2, wherein said controlled oxidizing ambient is established by establishing one of a wet chemical ambient and a gaseous ambient without using a plasma atmosphere.

5. The method of claim 1, wherein forming said cap layer comprises depositing titanium by performing a physical vapor deposition process in an oxygen and nitrogencontaining ambient.

6. The method of claim 1, wherein forming said cap layer comprises depositing titanium oxide by performing a physical vapor deposition process in a nitrogen-containing ambient.

7. The method of claim 1, wherein said high-k dielectric material comprises hafnium.

8. The method of claim 1, wherein forming said electrode material comprises forming a placeholder material above said cap layer so as to form a replacement gate electrode structure, forming drain and source regions in said semiconductor region in the presence of said replacement gate electrode structure and replacing said placeholder material with said electrode material after forming said drain and source regions.

9. The method of claim 8, wherein replacing said placeholder material with said electrode material comprises removing said placeholder material and depositing at least a material containing said metal species for adjusting said work function and avoiding exposure of said semiconductor device to a hydrogen-containing ambient prior to and after depositing said at least a material.

10. The method of claim 1, further comprising forming a strain-inducing semiconductor material in said semiconductor region.

11. A method, comprising:
forming a gate electrode structure on a semiconductor region of a semiconductor device, said gate electrode structure comprising a titanium, nitrogen and oxygen-containing cap layer formed above a high-k dielectric material and a placeholder material formed above said cap layer;
forming drain and source regions in said semiconductor region; and
replacing said placeholder material with an electrode material after forming said drain and source regions, said electrode material comprising a metal species for adjusting a work function of said gate electrode structure.

12. The method of claim 11, wherein forming said gate electrode structure comprises depositing a titanium nitride material above said high-k dielectric material and performing a treatment on the basis of an oxygen species.

13. The method of claim 12, wherein forming said gate electrode structure comprises depositing said cap layer in a deposition ambient that concurrently comprises titanium, nitrogen and oxygen.

14. The method of claim 13, wherein depositing said cap layer comprises performing a physical vapor deposition process.

15. The method of claim 11, further comprising forming a strain-inducing semiconductor alloy in said semiconductor region prior to forming said drain and source regions.

16. The method of claim 11, wherein forming said gate electrode structure comprises depositing said high-k dielectric material so as to contain hafnium.

17. The method of claim 11, wherein forming said gate electrode structure comprises forming said cap layer on said high-k dielectric material.

18. The method of claim 11, wherein replacing said placeholder material with said electrode material comprises avoiding exposure of at least said metal species and said cap layer to a hydrogen gas.

19. A transistor device, comprising:
a gate electrode structure comprising a titanium, oxygen and nitrogen-containing cap layer on a gate insulation layer comprising a high-k dielectric material, said gate electrode structure further comprising an electrode material formed above said cap layer and comprising a work function adjusting species.

20. The transistor device of claim 19, wherein an oxygen distribution is substantially uniform in said cap layer.
